(19) United States
(12) Patent Application Publication
(10) Pub. No.: US 2015/0146391 A1
(43) Pub. Date: May 28, 2015

(54) ELECTRONIC DEVICE AND SECURING STRUCTURE FOR FIXING PRINTED CIRCUIT BOARD

(71) Applicant: HON HAI PRECISION INDUSTRY CO., LTD., NEW TAIPEI (TW)

(72) Inventor: KUAN-CHIH TSENG, New Taipei (TW)

(21) Appl. No.: 14/476,432

(22) Filed: Sep. 3, 2014

(30) Foreign Application Priority Data
Nov. 26, 2013 (CN) 2013106082833

(51) Int. Cl. H05K 7/14; H05K 5/00; H05K 5/02; F16M 13/02; H05K 5/03; H05K 7/18

(52) U.S. Cl. CPC H05K 7/1427; H05K 5/03; H05K 7/183; H05K 5/0217; F16M 13/02; H05K 5/0026
USPC 361/752; 248/314; 312/223.1

(57) ABSTRACT

A support block for securing a notched printed circuit board includes a first rib, a second rib, and a connector element. The second rib is opposite to and substantially parallel to the first rib. The connector element is positioned between, and substantially perpendicular to, the first rib and the second rib. When the connector element is insertable into a notch of a notched printed circuit board, the first rib and the second rib secures the printed circuit board.

### FIELD

The present disclosure relates to internal structure of electronic devices.

### BACKGROUND

Printed circuit boards are generally mounted on electronic devices by screws. However, the printed circuit board must be assembled to or disassembled from the electronic device by a screw driver.

### BRIEF DESCRIPTION OF THE DRAWINGS

Implementations of the present technology will now be described, by way of example only, with reference to the attached figures.

FIG. 1 is an isometric view of an electronic device with a securing structure and a printed circuit board.

FIG. 2 is an enlarged view of the securing structure of FIG. 1.

FIG. 3 is an isometric view of the printed circuit board of FIG. 1.

FIG. 4 is a view of the printed circuit board inserted into the securing structure of FIG. 1.

FIG. 5 is a perspective view of the electronic device of FIG. 1.

FIG. 6 is a cross-sectional view of the electronic device of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

The following disclosure is described in relation to electronic device with securing structure for printed circuit board.

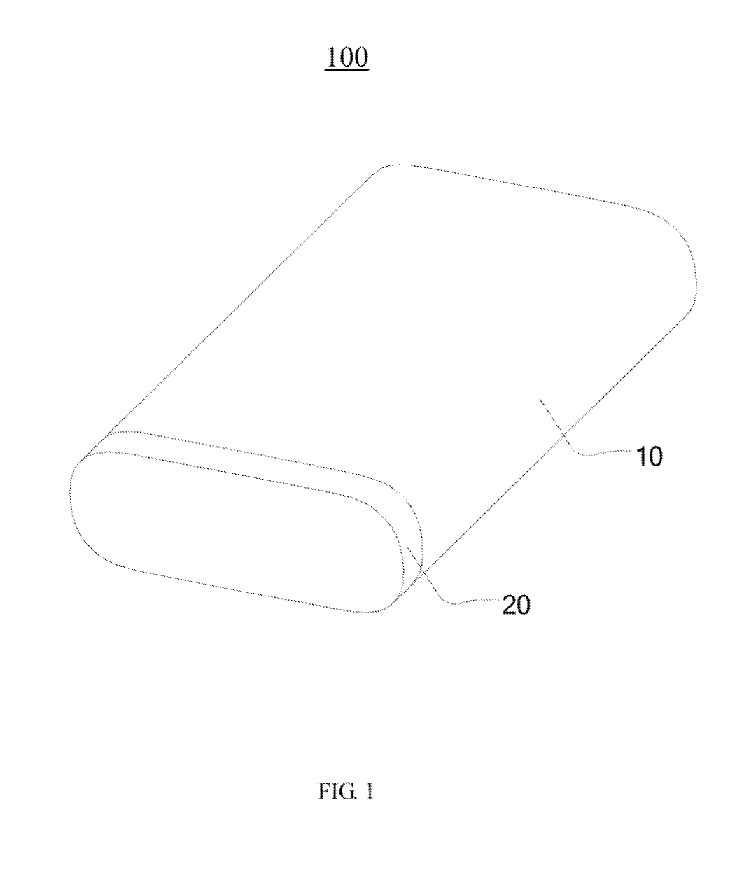

FIG. 1 illustrates an embodiment of an electronic device 100. The electronic device 100 includes a housing 10 and a cover 20 detachably covered on one end of the housing 10.

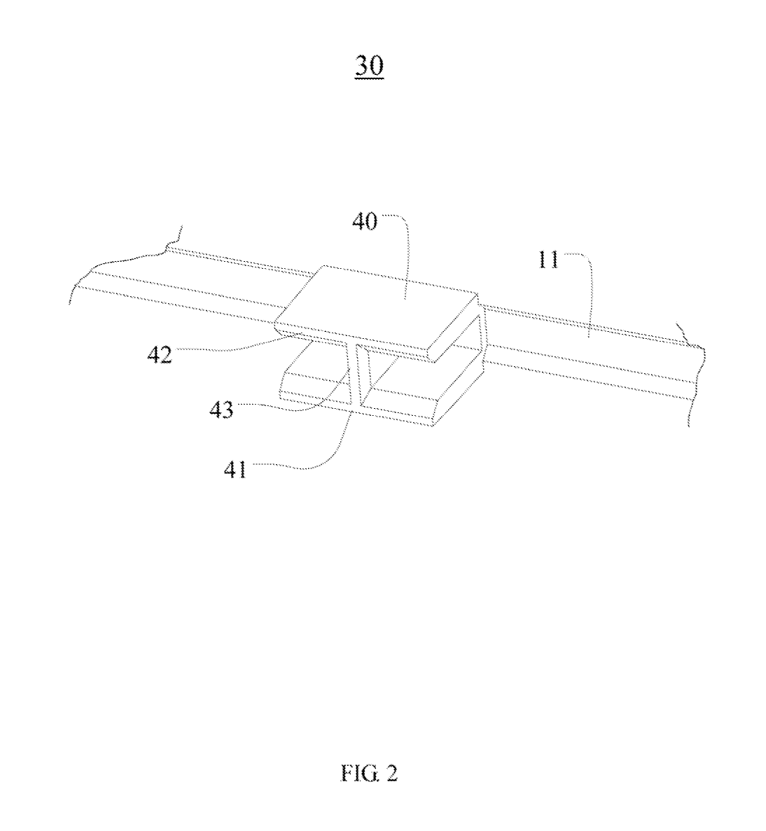

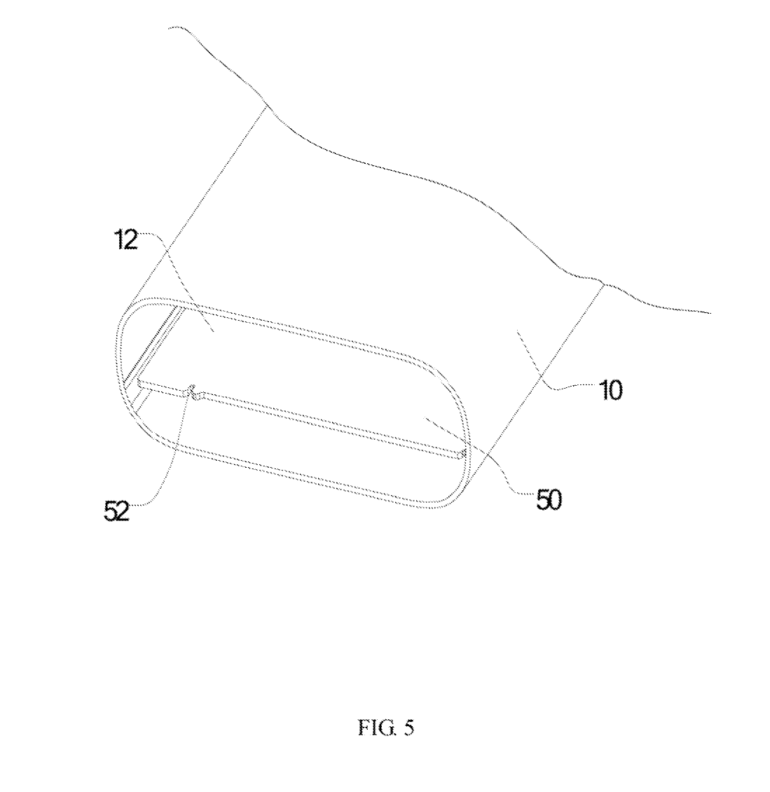

FIGS. 2 and 5 illustrates that the housing 10 is configured to form a cavity, an opening 12, and a first interior surface opposite the opening 12. The electronic device 100 further includes at least two securing structures 30. Each of the securing structure 30 includes a flange 11 and a support block 40. The flange 11 extends inward into the cavity from the first interior surface, the flange 11 has an outer end furthest from the interior surface. The support block 40 is attached to an edge of the flange 11. The support block 40 is in a shape of “H”. The support block 40 includes a first rib 41, a second rib 42 opposite to and parallel to the first rib 41, and a connector element 43 located between, and perpendicular to the first rib 41 and the second rib 42. At least one support block 40 is attached to the outer end of the flange 11 with the first rib 41 and second rib 42 substantially parallel to the flange 11. In the illustrated embodiment, at least one securing structure 30 is located inside the housing 10, and at least one securing structure 30 is located inside the cover 20. The cover 20 includes another flange 11 and another support block 40 attached to an edge of the another flange 11. The another block 40 includes another first rib 41, another second rib 42 opposite to and parallel to the another first rib 41, and another connector element 43 located between, and perpendicular to the another first rib 41 and the another second rib 42.

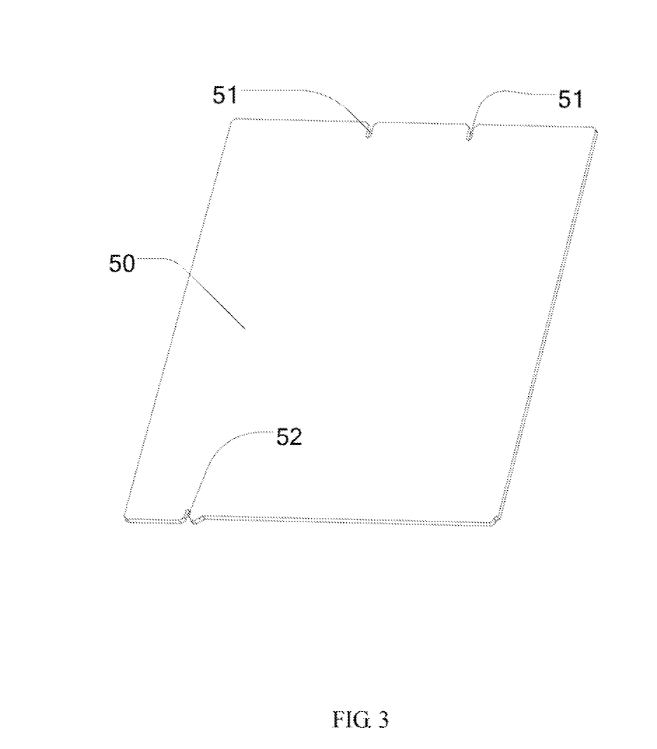

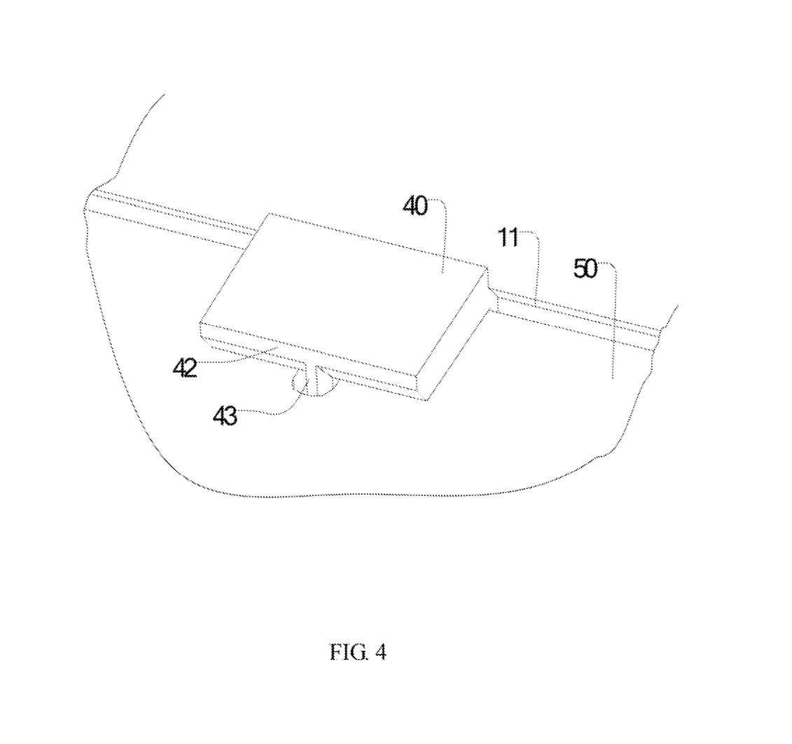

FIGS. 3-4 illustrate that the printed circuit board 50 is in a shape of rectangle. The printed circuit board 50 defines two first notches 51 in an end of the printed circuit board 50 adjacent to the flange 51, and a second notch 52 on another end of the printed circuit board 50, opposite to the first notch 51 and adjacent to the opening 12. One end of the printed circuit board 50 can be insertable within the connector element 43 to position the printed circuit board on the housing 10. The other end of the printed circuit board 50 opposite to the housing 10 can be insertable within the connector element 43 to position the printed circuit board 50 on the cover 20.

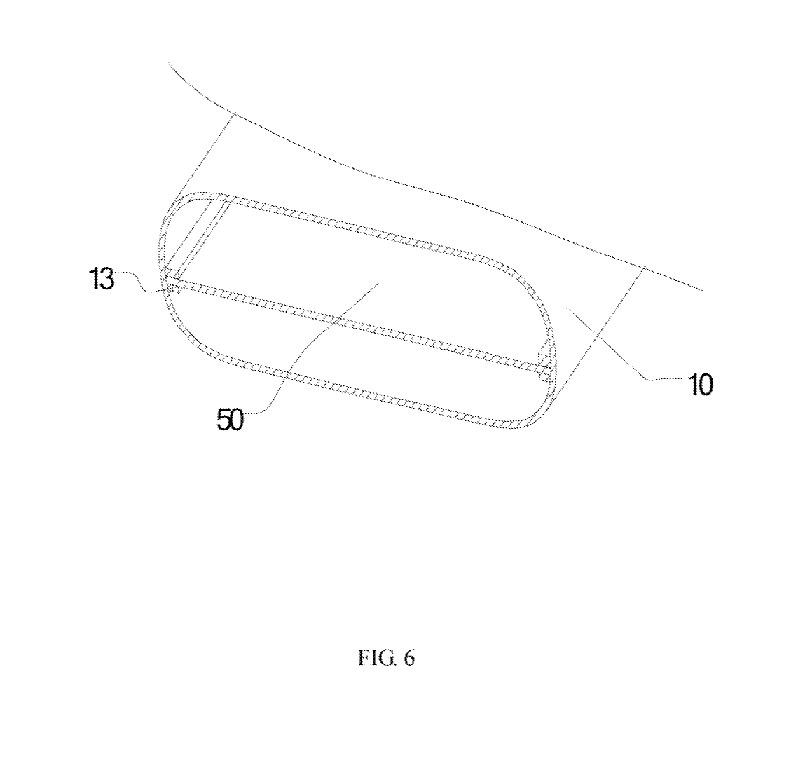

FIGS. 5-6 illustrate that the housing 10 further includes a pair of rails 13 located on two sides of the housing 10 and perpendicular to the flange 11. In assembly, first, the printed circuit board 50 slides along the rails 13 into the housing 10 until the connector element 43 is inserted into the first notches 51 allowing the first rib 41 and the second rib 42 of the housing 10 support one end of the printed circuit board 50. Secondly, the cover 20 is put over the opening 12 of the housing 10 so that the printed circuit board 50 is insertable into the connector element 43 of the cover 20 in the second notch 52 allowing the first rib 41 and the second rib 42 of the cover 20 support the other end of the printed circuit board 50. When the connector element 43 of the housing 10 is inserted into the first notch 51 and the connector element 43 of the cover 20 is inserted into the second notch 52, the printed circuit board 50 is securely fixed in the electronic device 100.

When the electronic device 100 is disassembled, first, the cover 20 is opened to disengage the second notch 52 from the connector element 43. Second, the printed circuit board 50 can be pulled out of the housing 10.

Many details are often found in the art such as the other features of a structure to fix a printed circuit board. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A support block for securing a notched printed circuit board, comprising:
a first rib;
a second rib, the second rib opposite to and substantially parallel to the first rib; and
a connector element positioned between, and substantially perpendicular to, the first rib and the second rib;
wherein, the connector element is insertable into a notch of a notched printed circuit board so that the first rib and the second rib secures the printed circuit board.

2. The support block of claim 1, wherein the connector element is coupled to the first rib and the second rib.

3. A securing structure for a printed circuit board, comprising:
a housing configured to form a cavity and having an opening, the housing having a first interior surface opposite the opening;
a flange extending inward into the cavity from the first interior surface, the flange having an outer end furthest from the interior surface; and
at least one support block, each support block comprising:
a first rib;
a second rib, the second rib opposite to and substantially parallel to the first rib;
a connector element positioned between, and substantially perpendicular to, the first rib and the second rib;
wherein, the at least one support block is attached to the outer end of the flange with the first rib and second rib substantially parallel to the flange; and
wherein, a printed circuit board with at least one notch is receivable in the housing so that the connector element of the at least one support block is insertable within the notch allowing the first rib and the second rib support the printed circuit board.

4. The securing structure of claim 3, wherein the connector element is coupled to the first rib and the second rib.

5. The securing structure of claim 3, wherein the housing further comprises a pair of rails, the rails are located on two sides of the housing perpendicular to the flange, the printed circuit board is inserted into the housing by sliding along the rails.

6. The securing structure of claim 5, wherein the printed circuit board defines a first notch in an end of the printed circuit board toward to the flange, the connector element is insertable within the first notch allowing the first rib and the second rib support the printed circuit board.

7. The securing structure of claim 6, wherein the printed circuit board defines a second notch in another end of the printed circuit board opposite to the first notch; the electronic device further comprises a cover and another securing structure located inside the cover, the cover is covered on one end of the housing, the another securing structure comprises another first rib, another second rib opposite to and substantially parallel to the another first rib, and another connector element positioned between, and substantially perpendicular to the another first rib and the another second rib, the another connector element of the cover is insertable within the second notch allowing the another first rib and the another second rib support the printed circuit board.

8. An electronic device receiving a printed circuit board, the electronic device comprising:
a housing;
a cover detachably covered on one end of the housing; and
at least two securing structure, one of the at least two securing structures located inside the housing and adjacent to the other end of the housing opposite to the cover, another one of the securing structures located inside the cover, the securing structure comprising:
a flange;
a first rib attached to the flange;
a second rib, the second rib opposite to and substantially parallel to the first rib; and
a connector element positioned between, and substantially perpendicular to, the first rib and the second rib;
wherein the printed circuit board is located between the first rib and the second rib, and the block is locked the printed circuit board.

9. The electronic device of claim 8, wherein the connector element is coupled to the first rib and the second rib.

10. The electronic device of claim 8, wherein the housing further comprises a pair of rails, the rails are located on two sides of the housing perpendicular to the flange, the printed circuit board is inserted into the housing by sliding along the rails.

11. The electronic device of claim 10, wherein the printed circuit board defines a first notch in an end of the printed circuit board toward to the flange, and the block is insertable within the first notch allowing the first rib and the second rib support the printed circuit board.

12. The electronic device of claim 11, wherein the printed circuit board defines a second notch in another end of the printed circuit board opposite to the first notch, the connector element of the cover is insertable within the second notch to make the printed circuit board located between the first rib and the second rib of the cover.

13. The electronic device of claim 12, wherein when the block of the housing is inserted into the first notch and the block of the cover is inserted into the second notch, the printed circuit board is fixed in the electronic device.
